(19) United States
(12) Patent Application Publication
(10) Pub. No.: US 2001/0004128 A1
(43) Pub. Date: Jun. 21, 2001

(54) Semiconductor package and manufacturing method thereof

(76) Inventors: Young Kuk Park, Seoul (KR); Doo Hwan Moon, Seoul (KR); Sun Ho Ha, Seoul (KR); Chang Suk Han, Seoul (KR)

Correspondence Address: James E. Parsons, SKJERVEN MORRILL MacPHERSON LLP, Suite 700, 25 Metro Drive, San Jose, CA, 95110-1349, US

(21) Appl. No.: 09/734,832

(22) Filed: Dec. 11, 2000

(30) Foreign Application Priority Data
Dec. 10, 1999 (KR) 1999-56410
Dec. 10, 1999 (KR) 1999-56413

(51) Int. Cl. H01L 29/768; H01L 21/00; H01L 31/113; H01L 21/44; H01L 21/48

(52) U.S. Cl. 257/680; 438/25; 438/60; 438/64; 438/127; 438/613

(57) ABSTRACT

Embodiments of a semiconductor package and manufacturing methods therefor are disclose. An exemplary package comprises an optical semiconductor chip having input and output pads on an upper surface thereof. A transparent plate is bonded to the chip via a dam located within the input and output pads. The chip is mounted within an aperture through a planar circuit board. Wires electrically connect the input and output pads to circuit patterns of the circuit board. An encapsulant fills the aperture, and supports the chip therein. Interconnects are formed on the lower surface of the circuit board. An alternative embodiment omits the dam and the wires and employs a flip chip style connection between the chip and circuit patterns on the transparent plate. The transparent is supported by and attached to the upper surface of the planar circuit board.

### BACKGROUND OF THE INVENTION

1. Field of the Invention

The present invention relates to a semiconductor package and a manufacturing method thereof, and more particularly, the present invention relates to a semiconductor package for an optical semiconductor chip and a manufacturing method for the package.

2. Description of the Related Art

Semiconductor packages are sometimes made to allow the transmission of light to or from an optical semiconductor chip mounted within the package. One type of optical semiconductor chip is a charge coupled device, or CCD. A CCD is used, for example, in an image signaling system of a television camera.

In a television camera, external light passes through lenses. Thereafter, the light is separated into three primary colors by a color separating optical system. The three primary colors are provided on, and form an image on, a light receiving active surface of the CCD. The CCD electronically scans the image to convert the image into an electrical signal, and then outputs the electrical signal.

A conventional semiconductor package for a CCD will be described below with reference to FIG. 6. The conventional semiconductor package 100′ has a CCD semiconductor chip 2, which has input and output pads 2a formed on an upper active surface thereof. The inactive lower surface of semiconductor chip 2 is bonded to a circuit board 10 by an adhesive. The circuit board 10 is not planar. Instead, circuit board 10 includes inward-facing vertically stepped portions 15′, which define a central cavity where the semiconductor chip 2 is located on a resin layer 11. A height of a first stepped portion 15′ is established in such a way as to be larger than a thickness of the semiconductor chip 2.

Circuit patterns, including bond fingers 12, are formed on an upper surface of the first stepped portion 15′ of the circuit board 10, and mounting pads 13′ are formed on an opposite lower surface of the circuit board 10. The circuit patterns and the mounting pads 13′ are connected with each other by conductive via-holes 14 extending through resin layer 11.

The input and output pads 2a of the semiconductor chip 2 and the bond fingers 12 of the circuit board 10 are electrically connected with each other by means of conductive wires 30.

A transparent glass plate 20 is bonded by an adhesive to an upper surface of an upper second stepped portion 15′ of the circuit board 10, thereby closing the internal cavity of circuit board 10 so as to protect the semiconductor chip 2, the conductive wires 30 and the like from the external environment and to enable the semiconductor chip 2 to easily receive light from an external source.

By virtue of the light that is received by the semiconductor chip 2, an electrical signal is transferred to a mother board (not shown) through the conductive wires 30, the conductive via-holes 14 and the mounting pads 13′.

However, the conventional semiconductor package constructed as mentioned above has disadvantages. For example, circuit board 10 is relatively expensive to make, since the stepped portion and internal cavity must be formed to allow the semiconductor chip and glass plate to be mounted to the circuit board. The fact that the stepped portions are formed at precise locations, and that the circuit patterns are formed on the stepped portions makes the manufacturing procedure relatively complicated. Complexity entails additional cost. Moreover, since the semiconductor chip is positioned in a cavity of the circuit board, the thickness and volume and so forth of the semiconductor package are relatively large.

### SUMMARY OF THE INVENTION

An object of the present invention is to provide a semiconductor package for a CCD semiconductor chip or some other type of optical semiconductor chip (i.e., a light sensing or light emitting semiconductor chip, for instance an EEPROM or laser diode) in such a way as to reduce manufacturing cost and complexity and, enable a thinner semiconductor package.

Another object of the present invention is to provide a semiconductor package which has mounted thereon a CCD semiconductor chip or another type of optical semiconductor chip in a flip chip style mounting, thereby eliminating the need for wire bonds to be connected between the semiconductor chip and the circuit board.

Another object of the present invention is to provide effective and efficient methods of manufacturing such semiconductor packages.

The present invention includes packages and methods that achieve all or some of these objects, as well as providing other advantages that will be apparent from the following discussion.

For example, one embodiment of the present invention is a semiconductor package comprising: a semiconductor chip having an upper surface with input and output pads formed thereon; a transparent plate (e.g., a glass plate) supported over and bonded to the upper surface of the semiconductor chip by a dam on the surface of the semiconductor chip; a planar circuit board including a resin layer, wherein the resin layer has an aperture formed through it such that the semiconductor chip can be positioned in the aperture, the resin layer having first circuit patterns including bond fingers that are formed on an upper surface of the resin layer, and second circuit patterns including lands that are formed on a lower surface of the resin layer, the first and second circuit patterns being connected with each other through conductive via-holes; conductive wires for electrically connecting the input and output pads of the semiconductor chip and the bond fingers of the circuit board; an encapsulating material for encapsulating the input and output pads of the semiconductor chip and the conductive wires and for filling the aperture between an inner surface of the circuit board and an outer side surface of the semiconductor chip; and input and output connectors formed on the lands of the lower surface of the circuit board.

In such an embodiment, the lower surfaces of the semiconductor chip, the encapsulating material and the circuit board can be flush one with another, i.e., in the same horizontal plane. The dam may be selected from a group consisting of a film adhesive and a double-sided adhesive tape. The encapsulating material may be selected from a group consisting of an epoxy molding compound and a liquid phase encapsulating material. The surface portions of the circuit patterns of the circuit board, excluding the bond fingers and the lands, may be coated with cover coats. Finally, the input and output pads may be one selected from a group consisting of a conductive plate layer and a conductive ball.

According to another aspect of the present invention, an embodiment of a method for manufacturing a semiconductor package comprises the steps of: providing a planar circuit board including a resin layer, the resin layer having an aperture of a predetermined size formed through it such that a semiconductor chip can be positioned in the aperture, the resin layer having first circuit patterns including bond fingers on an upper surface of thereof and second circuit patterns including lands on a lower surface thereof, the first and second circuit patterns being electrically connected with each other through the resin layer by conductive via-holes; applying a tape to the lower surface of the resin layer of the circuit board, thereby closing a lower end of the aperture; bonding a semiconductor chip to the tape such that input and output pads of the chip are oriented in a direction opposite the tape; attaching a transparent plate to an upper surface of the semiconductor chip by the medium of a dam; electrically connecting the input and output pads of the semiconductor chip and the bond fingers of the circuit board with each other using conductive wires; encapsulating the input and output pads of the semiconductor chip, the bond fingers, and the conductive wires and filling the aperture between an inner surface of the circuit board the cavity and an outer side surface of the semiconductor chip with an encapsulating material; and forming input and output connectors on the lands of the circuit board.

In such an embodiment, the dam may be selected from a group consisting of a film adhesive and a double-sided adhesive tape. The transparent plate may be affixed to a dam previously applied onto on the upper surface of the semiconductor chip before the semiconductor chip is placed in the aperture and attached to the tape. The encapsulating step may be selected from a group consisting of molding an epoxy molding compound and pouring a liquid phase encapsulating material. The step of forming the input and output connectors may be implemented by forming of conductive plate layers or conductive balls on the lands of the circuit board.

The semiconductor chip to which the transparent plate is attached may be fabricated by the steps of: providing a semiconductor wafer that includes a plurality of semiconductor chips each having input and output pads; on an upper active surface thereof; forming a dam of a predetermined height on the upper surface of each semiconductor chip, using a film adhesive, a double-sided adhesive tape or the like, in a manner such that the input and output pads are positioned outside the dam; attaching a transparent plate to each dam; and singulating respective semiconductor chips from the wafer. Subsequently, the semiconductor chips with the transparent plates pre-mounted thereon may be placed in the aperture of the circuit board.

The above described semiconductor packages of having advantages including that, since the semiconductor chip is positioned in an aperture through the circuit board, and the transparent plate is closely supported over the upper surface of the semiconductor chip with only the thickness of the dam between them, the thickness and volume and the like of the entire semiconductor package are decreased. Moreover, since it is not necessary to form internal stepped portions in a cavity of the circuit board, as in the conventional art, the manufacturing cost of the semiconductor package is reduced and manufacturing processes are simplified. Moreover, because a lower surface of the semiconductor chip is directly exposed to the outside, heat that in the semiconductor chip can be easily dissipated to the external environment.

In accordance to still another aspect of the present invention, an embodiment of a semiconductor package comprises: a semiconductor chip having on input and output pads on an upper surface thereof; a planar circuit board having a resin layer, the resin layer having an aperture of a predetermined size through it such that the semiconductor chip can be positioned in the aperture, the resin layer having first circuit patterns including bond fingers formed on an upper surface of the resin layer and second circuit patterns including lands formed on a lower surface of the resin layer, the first and second circuit patterns being electrically connected with each other through conductive via-holes; a transparent plate positioned on upper surfaces of the semiconductor chip and the bond fingers of the circuit board, the transparent plate having third circuit patterns on a lower surface thereof that are electrically connected between input and output pads of the semiconductor chip and respective corresponding bond fingers of the circuit board; conductive bumps for electrically connecting opposing inner and outer ends of the third circuit patterns of the transparent plate and the input and output pads of the semiconductor chip and the bond fingers of the circuit board, respectively; and input and output connectors formed on the lands of the lower surface of the circuit board, in such a way as to enable the package to be mounted to a mother board.

An encapsulating material can optionally be used fill the aperture between an inner surface of the circuit board and an outer side surface of the semiconductor chip. Moreover, the input and output connectors of the package can be selected from a group consisting of conductive plate layers and conductive balls.

An exemplary method of making such a semiconductor package comprises the steps of: providing a transparent plate which has first circuit patterns on a lower surface thereof; forming conductive bumps on opposing inner and outer ends of the first circuit patterns of the transparent plate; positioning a semiconductor chip adjacent the lower surface of the transparent plate and electrically connecting respective input and output pads of the semiconductor chip to the conductive bumps that were formed on an inner end of the first circuit patterns of the transparent plate; providing a planar circuit board having a resin layer, the resin layer having an aperture of a predetermined size through it such that the semiconductor chip can be positioned in the aperture, the resin layer having second circuit patterns that include bond fingers formed on an upper surface of the resin layer and third circuit patterns that include lands formed on a lower surface of the resin layer, the second and third circuit patterns being electrically connected with each other through conductive via-holes; positioning the semiconductor chip having the transparent plate previously attached thereto in the aperture of the resin layer of the circuit board and electrically connecting conductive bumps on the outer ends of the first circuit patterns the bond fingers of the second circuit patterns; and forming input and output connectors on the lands of the third circuit patterns of the circuit board.

In such a method, the steps of electrically connecting the first circuit patterns of the transparent plate, input and output pads of the semiconductor chip and the bond fingers of the circuit board with one another can be implemented in a manner such that, after positioning the semiconductor chip in the aperture of the circuit board, the transparent plate may be placed so that the inner and outer conductive bumps are juxtaposed with the input and output pads of the chip and the bond fingers, and then the plate may be squeezed against the input and output pads of the semiconductor chip and the bond fingers of the circuit board simultaneously, thereby electrically connecting the semiconductor chip with the circuit patterns of the upper surface of the circuit board through the first circuit patterns of the transparent plate and the bumps.

Consequently, in this embodiment, bond wires are unnecessary because the semiconductor chip is electrically connected to the circuit patterns of the transparent plate in a flip chip style connection. Further, since there is no need for the transparent plate to clear an apex of the bond wire loops, as is the case in FIG. 6, the transparent plate can be very close to the upper surface of the semiconductor chip, thereby achieving a thin package. Only the height of the conductive bumps separate the transparent plate from the upper surfaces of the circuit board and the chip. In addition, because a lower surface of the semiconductor chip is exposed to the external environment, heat generated in the semiconductor chip can be easily dissipated to the external environment.

In this method, the conductive bumps can be formed in advance on the input and output pads of the semiconductor chip and the bond fingers of the circuit board. Thereafter, the transparent plate can be juxtaposed with and electrically connected to the pairs of bumps.

The above method can further comprise the optional step of filling the aperture between an inner surface of the circuit board and an outer side surface of the semiconductor chip with an encapsulating material. The input and output connectors can be selected from a group consisting of conductive plate layers and conductive balls.

### BRIEF DESCRIPTION OF THE DRAWINGS

The above objects, and other features and advantages of the present invention will become more apparent after a reading of the following detailed description when taken in conjunction with the drawings, in which:

FIGS. 1A and 1B are cross-sectional side views respectively illustrating semiconductor packages in accordance with first and second embodiments of the present invention;

FIGS. 2A through 2G are cross-sectional side views of stages in an exemplary method of manufacturing semiconductor packages in accordance with the first and second embodiments of the present invention;

FIGS. 3A through 3D are plan views of stages in an exemplary process for bonding a glass plate onto an upper surface of a semiconductor chip in accordance with the first and second embodiments of the present invention;

FIGS. 4A and 4B are cross-sectional side views respectively illustrating semiconductor packages in accordance with third and fourth embodiments of the present invention;

FIGS. 5A through 5F are cross-sectional side views of stages in an exemplary method of manufacturing semiconductor packages in accordance with the third and fourth embodiments of the present invention; and

FIG. 6 is a cross-sectional side view of a conventional semiconductor package for a charge coupled device (CCD).

### DETAILED DESCRIPTION OF EXEMPLARY EMBODIMENTS

Exemplary embodiments of the present invention are illustrated in the accompanying drawings. Wherever possible, the same reference numerals will be used throughout the drawings and the description to refer to the same or like parts.

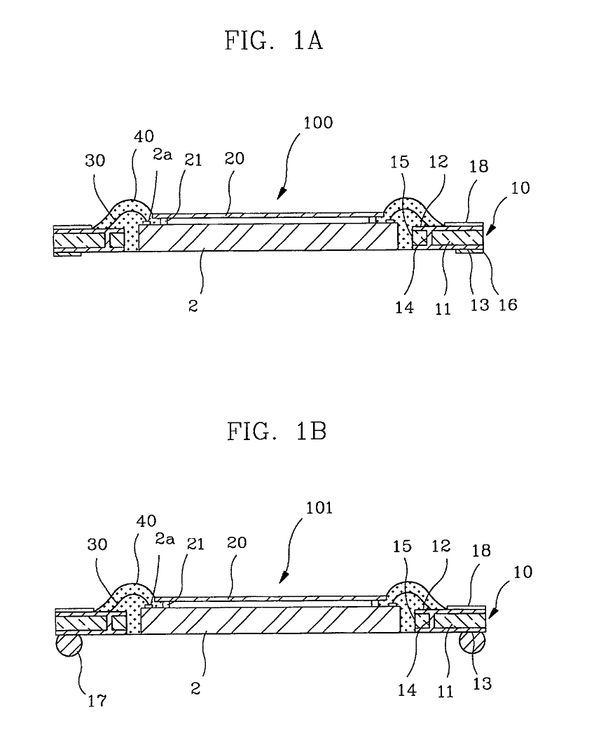

FIGS. 1A and 1B are cross-sectional side views respectively illustrating semiconductor packages 100 and 101 in accordance with first and second embodiments of the present invention.

First, a CCD or other optical semiconductor chip 2 is provided that has input and output pads 2a formed on an active upper surface thereof. A transparent plate 20 formed of optically clear glass, plastic, quartz or the like is positioned over and transmits light to (or from) the upper surface of the semiconductor chip 2, and is supported thereon by a dam 21. In this example, a glass plate 20 is used. Glass plate 20 enables the semiconductor chip 2 to easily receive light from an external source.

In this example, a double-sided ring of adhesive tape or the like is used to form dam 21. However, a diversity of adhesive materials, e.g., a flowable, hardenable epoxy-based or other adhesive resin material, can be used to form the dam 21, as practitioners will appreciate. Hence, dam 21 is not limited to a specific material.

The semiconductor chip 2 is positioned in an aperture 15 that extends through a planar circuit board 10. The aperture 15 is located at a center portion of the resin layer 11, and is sized so as to allow the semiconductor chip 2 to be positioned therein.

Circuit board 10 has a planar resin layer 11. First circuit patterns, which include bond fingers 12, are formed on a planar upper surface of the resin layer 11, and second circuit patterns, which include lands 13, are formed on a planar lower surface of the resin layer 11. Bond fingers 12 are proximate to radiate from the periphery of aperture 15. The first and second circuit patterns are electrically connected with each other by conductive via-holes 14 through resin layer 11. Surface portions of the first and second circuit patterns of the circuit board 10, excluding the bond fingers 12 and the lands 13, can be coated with insulative cover coats 18. The circuit patterns, that is, the first and second circuit patterns including the bond fingers 12 and the lands 13, respectively, and the intermediate portions of the circuit patterns that extend from the respective bond fingers 12 or lands 13 to via holes 14, may be formed of thin metal films, e.g., Cu, Alloy 42 or the like, or other electrically conductive materials. Via-holes 14 may be plated or filled with the same or similar metals or other electrically conductive materials.

Also, the bond fingers 12 are plated with Ag in a manner that allows the bond fingers 12 to be bonded with conductive wires 30 in a reliable way. Likewise, the lands 13 are plated with Au, Ag, Ni, Pd and so forth, in a manner such that allows the lands 13 to be bonded with input and output connectors, such as balls 17 (FIG. 1B), in a reliable way.

Also, while in this example that the circuit board 10 comprises a printed circuit board (e.g., a glass fiber filled organic laminate) that has circuit patterns formed on the upper and lower surfaces of a resin layer 11, other embodiments may alternatively use a circuit tape, a circuit film, or the like to constitute the circuit board 10. This is a matter of choice for persons skilled in the art, and, therefore, does not limit the present invention.

The input and output pads 2a of the semiconductor chip 2 and the bond fingers 12 of the circuit board 10 are electrically connected with each other by conductive wires 30 or the like. Wires 30 may be formed of gold or aluminum. The bonded wires provide an electrically conductive path between the semiconductor chip 2 and the bond fingers 12.

An encapsulating material 40 encapsulates the input and output pads 2a of the semiconductor chip 2, a peripheral portion of the upper surface of semiconductor chip 2 outside of dam 21, conductive wires 30, bond fingers 12, and an inner subportion of the upper surface of circuit board 10 around aperture 15. Encapsulating material 40 also fills aperture 15, and in particular fills the space between an orthogonal inner surface of the resin layer 11 of the circuit board 10 and a peripheral side surface of the semiconductor chip 2. Encapsulating material 40 protects those components from the external environment, and fixes the semiconductor chip 2 to circuit board 10 within aperture 15.

The lower inactive surface of the semiconductor chip 2 and the lower surfaces of encapsulating material 40 and circuit board 10 are flush one with another, i.e., are in the same horizontal plane. Since the lower surface of the semiconductor chip 2 is exposed to the external environment, heat generated inside the semiconductor chip 2 can be easily dissipated to the external environment.

Encapsulating material 40 can be an epoxy molding compound that is molded in place using a mold, or a liquid phase encapsulating material that is poured using a dispenser. Again, the encapsulating material and the encapsulating method used are matters of choice for a person skilled in the art and, therefore, are not limiting.

Care is taken that encapsulating material 40 is not placed on the optical circuitry on the inner portion of the active upper surface of the semiconductor chip 2, over which glass plate 20 is adhesively mounted on dam 21, or on the central upper surface of glass plate 20. By virtue of the contact between dam 21 and a lower surface of the glass plate 20, the encapsulating material 40 is prevented from leaking into a space defined between the glass plate 20 and the upper surface semiconductor chip 2, and dam 21.

In FIG. 1A, conductive plate layers 16, for example, solder plate layers, are formed on the lands 13 the lower surface of the circuit board 10, thereby forming input and output connectors. Accordingly, the semiconductor package 100 can be mounted in an electrically conductive manner on a mother board (not shown) by fusing plate layers 16 to corresponding circuit patterns or the like of the motherboard.

On the other hand, as shown for semiconductor package 101 of FIG. 1B, conductive balls 17, for example, solder balls, can be fused to the lands 13 so as to serve as the input and output connectors.

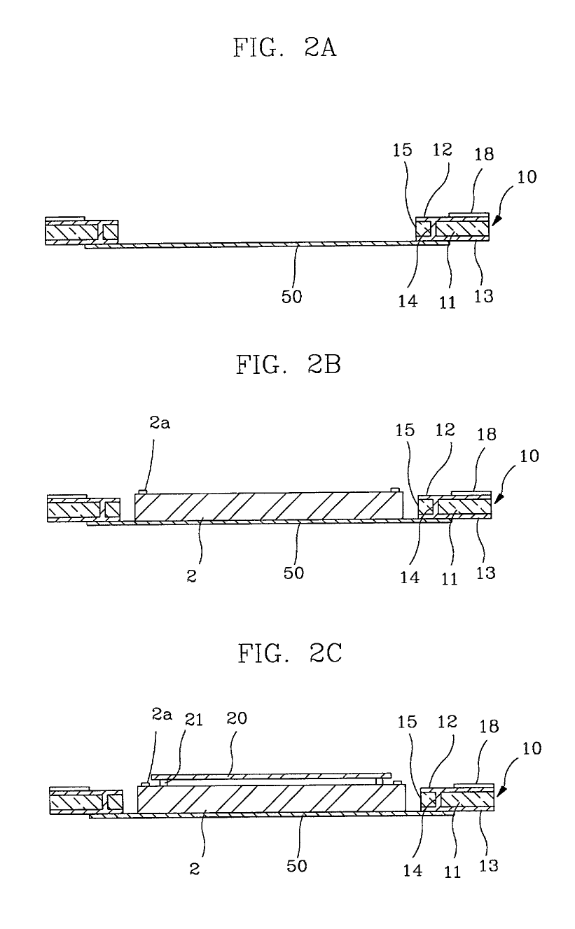

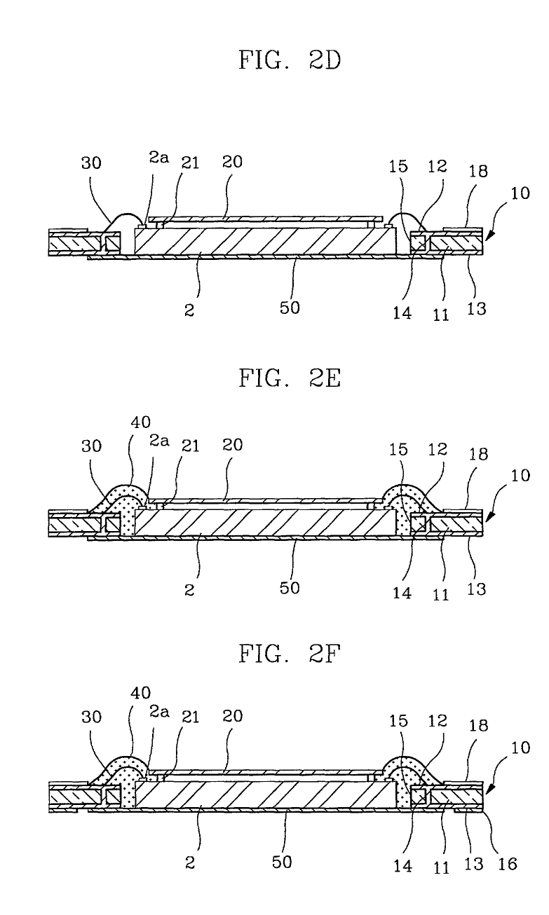

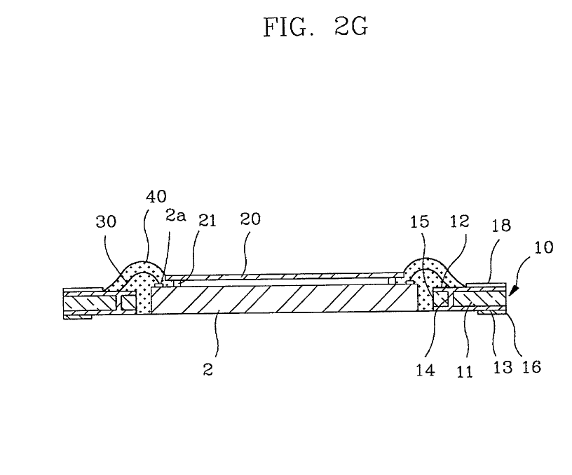

FIGS. 2A through 2G are cross-sectional views of stages in an exemplary embodiment of a method for manufacturing semiconductor packages 100 and 101 of FIGS. 1A and 1B, respectively. Practitioners will appreciate that the order of the steps may vary.

First, referring to FIG. 2A, the planar circuit board 10 is provided. An aperture 15 is drilled, punched or otherwise defined through the resin layer 11 in a manner such that the semiconductor chip 2 can be positioned in the aperture 15. The first circuit patterns, which include the bond fingers 12, are formed on the upper surface of the resin layer 11, and the second circuit patterns, which include the lands 13, are formed on the lower surface of the resin layer 11. The first and second circuit patterns are electrically connected with each other through resin layer 11 by the conductive via-holes 14.

Here, the surface portions of the first and second circuit patterns, excluding the bond fingers 12 and the lands 13, can be coated with the cover coats 18. Also, as described above, a circuit tape or circuit film can be used to constitute the circuit board 10.

Next, a tape 50 is attached to the lower surface of the circuit board 10 in such a way as to close a lower end of the aperture 15 (see FIG. 2A). The entire upper surface of the tape 50 has an adhesive layer thereon.

Next, as shown in FIG. 2B, the inactive bottom surface semiconductor chip 2 is adhesively bonded to the upper surface of the tape 50. By applying heat and pressure, the semiconductor chip 2 can be more stably bonded to the tape 50.

Referring to FIG. 2C, dam 21 is applied onto the upper surface of the semiconductor chip 2 inside the input and output pads 2a on the upper surface of the semiconductor chip 2. Typically, dam 21 will have the form of a ring. As mentioned above, the dam 21 can comprise a variety of adhesive materials, such as a film adhesive, a double-sided adhesive tape, a curable resin or the like. Subsequently, glass plate 20 is placed on an upper surface of dam 21 over the active upper surface of semiconductor chip 2. Glass plate 20 is adhesively fixed to and supported over the upper surface of semiconductor chip 2 by dam 21.

Alternatively, it can be contemplated that, before the semiconductor chip 2 is bonded to the tape 50, dam 21 may be provided on the upper surface of the semiconductor chip 2, and then glass plate 20 may be placed on dam 21 and thereby be attached to the upper surface of the semiconductor chip 2 before semiconductor chip 2 is placed on and bonded to the tape 50. This alternative will be described later in greater detail.

Referring now to FIG. 2D, the input and output pads 2a of the semiconductor chip 2 and the bond fingers 12 of the circuit board 10 are electrically connected with each other using a conductor, e.g., conductive wires 30.

Subsequently, referring to FIG. 2E, the input and output pads 2a of the semiconductor chip 2, conductive wires 30, input and output pads 2a, and bond fingers 12 are encapsulated by the encapsulating material 40. The encapsulating material 40 also fills aperture 15, and covers the orthogonal inner surface of the resin layer 11 the outer side surfaces of the semiconductor chip 2. The encapsulating material 40 can comprise an epoxy molding compound formed in a mold or a liquid phase encapsulating material poured using a dispenser. Encapsulant material 40 is then hardened. Again, care is taken that the upper surface of the glass plate 20 and the upper surface of semiconductor chip 2 inside dam 21 is not covered by the encapsulating material 40. Dam 21 keeps encapsulating material 40 off of the active surface of semiconductor chip 2 inside dam 21.

Subsequently, conductive plate layers 16 are formed on the lands 13 of the circuit board 10 (FIG. 2F). Alternatively, conductive balls 17 are fused to the lands 13 of the circuit board 10 (see FIG. 1B). The conductive plate layers 16 or the conductive balls 17 can respectively comprise solder plate layers or solder balls. It is to be noted that the present invention is not confined to these types of interconnect means.

Finally, referring to FIG. 2G, tape 50 on the lower surface of the circuit substrate 10 may be removed, thereby exposing the lower surface of the semiconductor chip 2 to the external environment. Tape 50 may be UV or heat sensitive tape for easy removal. Tape 50 may also be left in place, particularly if tape 50 is a thermally conductive tape.

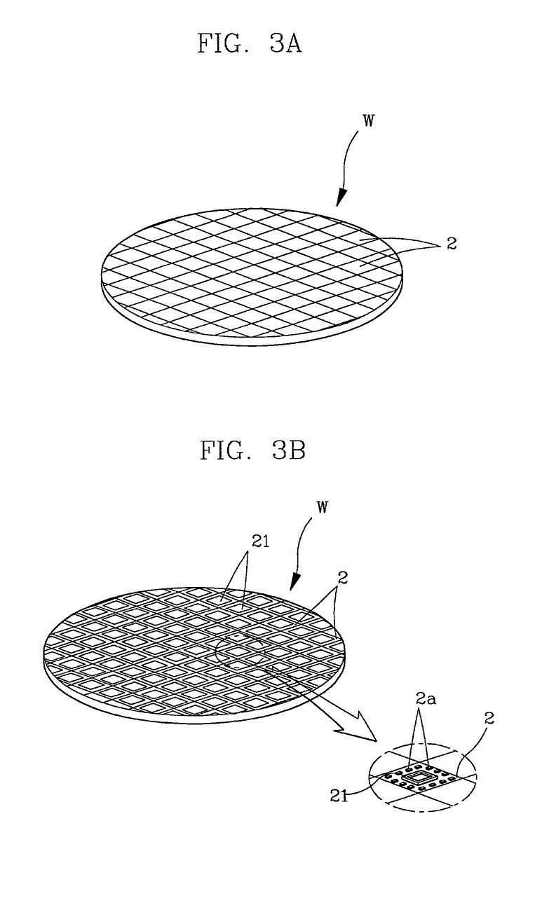

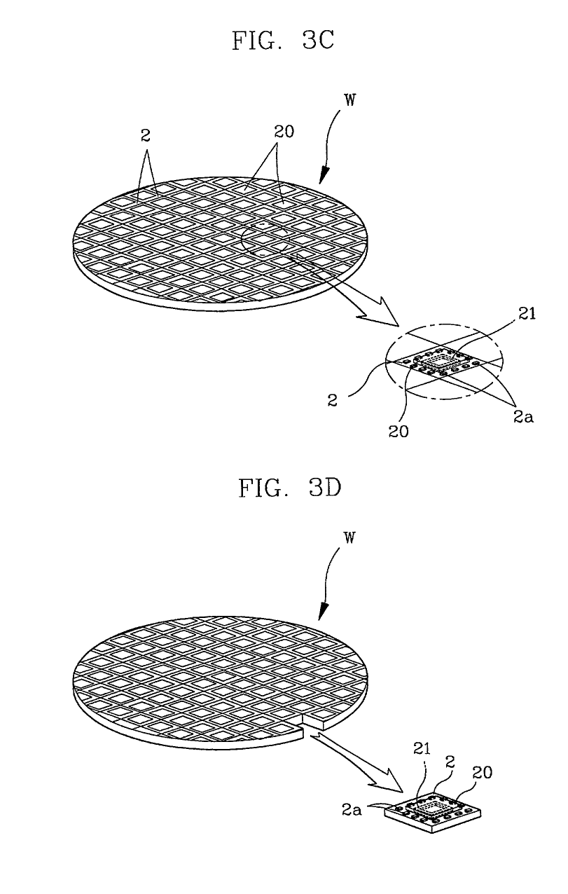

FIGS. 3A through 3D are cross-sectional views for explaining stages in an alternative process for bonding the glass plate 20 to the upper surface of the semiconductor chip 2 of the semiconductor packages 100 and 101.

As shown in FIGS. 3A through 3D, a conventional semiconductor wafer W having with a plurality of undiced semiconductor chips 2 is provided. The input and output pads 2a are formed on the upper surface of each semiconductor chip 2 (see FIG. 3B).

Thereafter, a square ring dam 21 of a predetermined height, which may be a film adhesive, a double-sided adhesive tape or the like, is attached to the upper surface of the semiconductor chip 2, in a manner such that the input and output pads 2a are positioned outside the dam 21.

Next, referring to FIG. 3C, the glass plate 20 is placed on and attached to the upper surface of dam 21, and thereby is adhesively supported over the upper surface of the semiconductor chip 2.

Thereupon, the respective semiconductor chips 2 are singulated from the wafer W, thereby providing a multitude of semiconductor chips 2 each having a glass plate 20 attached thereto.

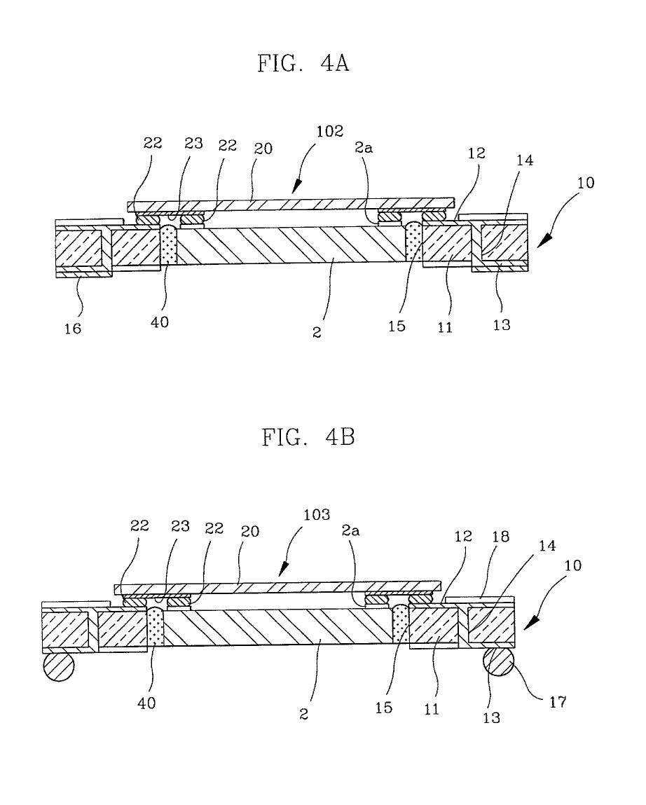

FIGS. 4A and 4B are cross-sectional side views respectively illustrating semiconductor packages 102 and 103 in accordance with third and fourth embodiments of the present invention.

With respect to semiconductor package 102 of FIG. 4A, a semiconductor chip 2 having input and output pads 2a on an upper surface thereof is positioned in an aperture 15 through a circuit board 10. Lower surfaces of the semiconductor chip 2 and the circuit board 10 are flush with each other, i.e., are in the same horizontal plane.

As above, planar circuit board 10 includes a resin layer 11. First circuit patterns, which include bond fingers 12, are formed on a planar upper surface of the resin layer 11, and second circuit patterns, which include lands 13, are formed on a planar lower surface of the resin layer 11. The first and second circuit patterns are connected with each other by conductive via-holes 14 through resin layer 11. Also, as described above, the aperture 15 through a center portion of the resin layer 11, and is sized such that the semiconductor chip 2 can be positioned in the aperture 15. Surface portions of the first and second circuit patterns, excluding the bond fingers 12 and the lands 13, are coated with cover coats 18. The circuit patterns, that is, the first and second circuit patterns, including the bond fingers 12 and the lands 13, have the form of thin metal films that may be made of Cu, Alloy 42 or the like. Other conductive materials also may be used.

Also, the bond fingers 12 are plated with Ag in a manner such that the bond fingers 12 may be bonded with conductive bumps 22 (see below) in a reliable way. The lands 13 are plated with Au, Ag, Ni, Pd and so forth, in a manner such that the lands 13 may be bonded with input and output connectors in a reliable way.

Also, while the example circuit board 10 comprises a planar printed circuit board having circuit patterns are respectively formed on the upper and lower surfaces of a resin layer 11, in other embodiments a circuit tape, a circuit film or the like can be used to constitute the circuit board 10. This is a matter of choice for the practitioner.

Glass plate 20 is positioned over and spans the entire upper surface of the semiconductor chip 2. Glass plate 20 also is sized such that its peripheral area extends over an inner subportion of the upper surface of circuit board 10 around aperture 15, including over bond fingers 12 of the circuit board 10. Third circuit patterns 23, which may have the form of thin metal films, are formed on a lower surface of the glass plate 20, i.e., on the surface of glass plate 20 that is juxtaposed with the upper surfaces of semiconductor chip 2 and circuit board 10. The third circuit patterns 23 electrically connect the input and output pads 2a of the semiconductor chip 2 to the bond fingers 12 of the circuit board 10.

Conductive bumps 22, such as gold bumps 22, are formed at opposing inner and outer ends of each of the third circuit patterns 23. The inner and outer conductive bumps 22 are respectively juxtaposed with and connected to an input and output pad 2a of the semiconductor chip 2 or to the corresponding bond finger 12 of the circuit board 10. Other conductive connective materials may be used for bumps 22, such as a conductive metal filled resin.

Third circuit patterns 23 can be directly formed on the lower surface of the glass plate 20 using conductive ink or the like. Alternatively, a circuit tape or circuit film upon which the third circuit patterns 23 are formed can be bonded to the lower surface of the glass plate 20.

Conductive plate layers 16, such as solder plate layers, are on the lands 13 of the lower surface of the circuit substrate 10. The conductive plate layers 16 can serve as input and output connectors. The input and output connectors are thereafter connected to terminals of a mother board, and function to transfer signals from the semiconductor chip 2 to the mother board, and vice versa.

Alternatively, as in semiconductor package 103 of FIG. 4B, the input and output connectors can be formed by fusing conductive balls 17, such as solder balls, to the lands 13 of the circuit substrate 10.

An encapsulating material 40 is optionally provided in aperture 15 of FIGS. 4A and 4B, thereby filling a space defined between an orthogonal inner surface of the resin layer 11 and an outer side surface of the semiconductor chip 2. Encapsulating material 40 thereby fixes semiconductor chip 2 to the circuit board 10 in a stable manner. The encapsulating material 40 comprises a liquid phase encapsulating material that is dispensed by a dispenser. There is a space between an upper surface of encapsulant material 40 and the lower surface of glass plate 20. The opposing lower surface of encapsulant material 40 is planar and in the same horizontal plane as the lower surface of semiconductor chip 2 and resin layer 11.

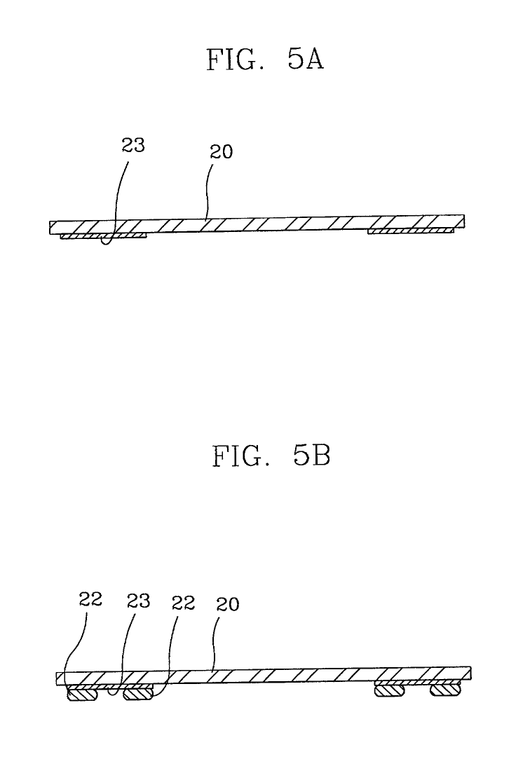

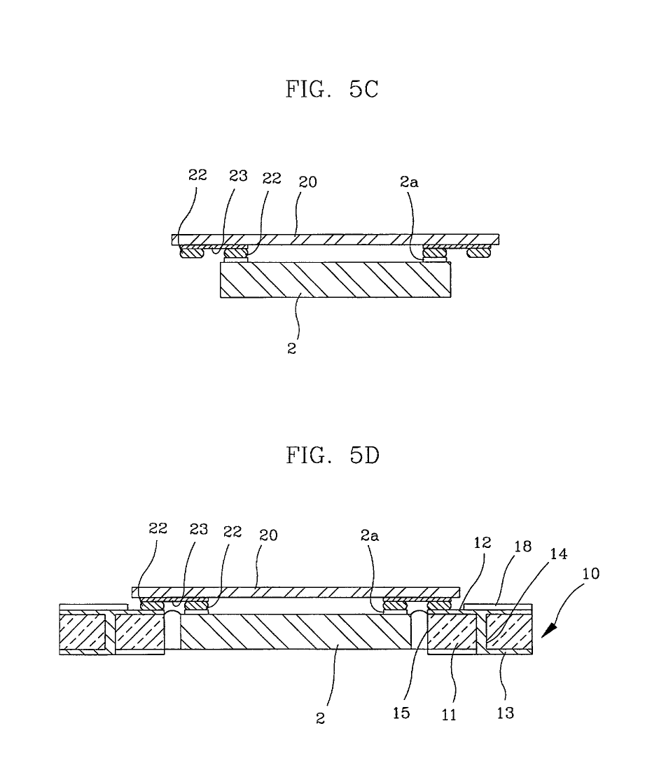

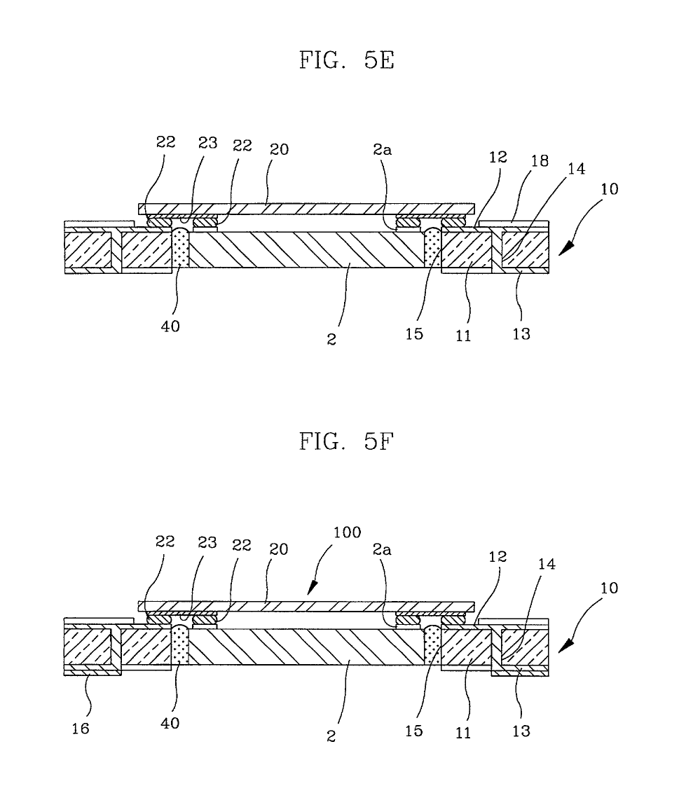

FIGS. 5A through 5F are cross-sectional views of stages in an exemplary method for manufacturing the semiconductor packages 102 and 103 of FIGS. 4A and 4B, respectively. Practitioners will appreciate that the order of the steps may vary.

First, referring to FIG. 5A, a glass plate 20 is provided which has electrically conductive third circuit patterns 23 on a lower surface thereof. The third circuit patterns 23 may be formed using conductive ink or by bonding thereto a circuit tape or the circuit film having conductive circuit patterns thereon.

Subsequently, conductive bumps 22, such as gold bumps 22, are formed at the opposing ends of the respective third circuit patterns 23 of the glass plate 20 (see FIG. 5B).

Referring now to FIG. 5C, the semiconductor chip 2, which has input and output pads 2a on its active surface, is positioned on the lower surface of the glass plate 20. In particular, the input and output pads 2a of the semiconductor chip 2 and the conductive bumps 22 at the inner end of the third circuit patterns 23 are juxtaposed and electrically connected with each other, thereby fixing semiconductor chip 2 to the lower surface of glass plate 20.

Thereupon, a planar circuit board 10 is provided, as is shown in FIG. 5D. Circuit board 10 has an aperture 15 through a central region of the resin layer 11 so that the semiconductor chip 2 can be positioned in the aperture 15. The first circuit patterns of circuit board 10, which include the bond fingers 12, are formed on the upper surface of the resin layer 11, and the second circuit patterns of circuit board 10, which include the lands 13, are formed on the lower surface of the resin layer 11. The first and second circuit patterns are electrically connected with each other by the conductive via-holes 14.

The semiconductor chip 2 is positioned in the aperture 15 of the circuit board 10 such that the conductive bumps 22 of the outer ends of the third circuit patterns 23 of the glass plate 20 are juxtaposed with the bond fingers 12 of the circuit board 10, and an electrical connection is formed between the respective juxtaposed bumps 22 and bond fingers 12. Accordingly, electrically conductive paths are formed between the input and output pads 2a of semiconductor chip 2 and the bond fingers 12 of the first circuit patterns on the upper surface of circuit board 10. The paths include third circuit patterns 23 on the lower surface of glass plate 20 and the pairs of opposing bumps 22.

Next, as shown in FIG. 5E, the encapsulating material 40 is optionally applied within aperture 15, including the space defined between the inner side surface of the resin layer 11 and the outer side surface of the semiconductor chip 2, thereby fixing the semiconductor chip to the circuit board 10 in a stable manner. Encapsulating material 40 does not cover the upper surfaces of circuit board 10 or semiconductor chip 2 at all, or only in trivial amounts, in this embodiment. Alternatively, the encapsulating material 40 can be omitted, since semiconductor chip 2 is supported in aperture 15 through a flip chip style connection to the third circuit patterns 23 on the juxtaposed surface of glass plate 20, which in turn is supported on and bonded to bond fingers 12 of the upper surface of circuit board 10.

Subsequently, conductive plate layers 16 (or the conductive balls 17) may be fused to the lands 13 of the circuit board 10, thereby forming input and output connectors that can be used for mounting the package mounted to a mother board (see FIG. 5F).

Conductive plate layers 16 and balls 17 may be omitted in cases where the lands of the second circuit patterns on the lower surface of the circuit board 10 are directly mated to the terminals of a motherboard.

The above-described steps of electrically connecting the third circuit patterns 23 of the glass plate 20, the input and output pads 2a of the semiconductor chip 2 and the bond fingers 12 of the circuit board 10 can be implemented in various ways.

For example, semiconductor chip 2 may be positioned in the aperture 15 of the circuit board 10 on an adhesive tape 50 (see FIG. 2B), and subsequently glass plate 20 of FIG. 5B may be juxtaposed with the upper surfaces of the semiconductor chip 2 and the circuit board 10, and then placed squarely onto the input and output pads 2a of semiconductor chip 2 and the bond fingers 12 of circuit board 10, such the input and output pads 2a of the semiconductor chip 2 and the bond fingers 12 of the circuit board 10 may be simultaneously electrically connected with the conductive bumps 22 that are present at the opposing inner and outer ends of the third circuit patterns 23 of the glass plate 20.

As a further alternative, it can be envisioned that, a glass plate 20 to which conductive bumps 22 are fused may be positioned on the bond fingers 12 of the circuit board 10, and electrically connected thereto through the outer bumps 22. Subsequently, the semiconductor chip 2 may be positioned in the aperture 15 of the circuit board 10 so that the input and output pads 2a of the semiconductor chip 2 and inner bumps 22 of glass plate 20 are juxtaposed for electrical connection with each other. Thus, the step of electrically connecting the third circuit patterns 23 of the glass plate 20, the semiconductor chip 2, and the circuit board 10 with one another can be implemented in a variety of ways.

Of course, instead of initially forming conductive bumps 22 at both ends of the third circuit patterns 23 of the glass plate 20, it can be contemplated that, the conductive bumps 22 may instead be initially provided on the input and output pads 2a of the semiconductor chip 2 and the bond fingers 12 of the circuit board 10. Subsequently, after semiconductor chip 2 is supported within aperture 15 on a tape 50 (not shown), a glass plate 15 having third circuit patterns 23 thereon may be placed over the upper surfaces of circuit board 10 and semiconductor chip 2 so that each third circuit pattern is juxtaposed with a pair of bumps 22 so that an electrical connection can be formed between them through the bumps 22 and third circuit patterns 23.

The semiconductor packages described herein may be made in matrix form on a large planar circuit board substrate having a matrix of sites each for the assembly of one of the packages. The matrix subsequently is cut to singulate individual completed packages. The methods described herein are readily adaptable to such parallel processing methods.

In the drawings and specification, there have been disclosed exemplary embodiments of the invention and, although specific terms are employed, they are used in a generic and descriptive sense only and not for purposes of limitation, the scope of the invention being set forth in the following claims.

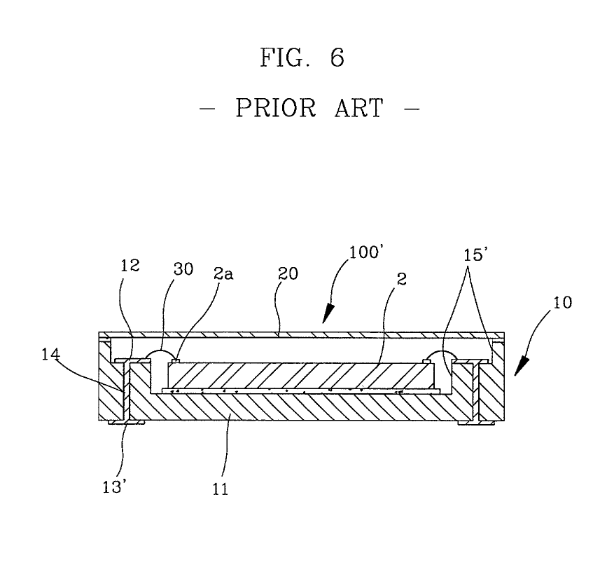

Advantageously, the exemplary embodiments described above have an optical semiconductor chip that is positioned in an aperture through the planar circuit board. Accordingly, the thickness and volume and the like of the entire semiconductor package are decreased in comparison to the conventional package of FIG. 6. Moreover, since it is not necessary to form an internal cavity in the circuit board that has stepped sidewalls with circuit patterns thereon, as in the conventional art, the manufacturing cost of the semiconductor package is reduced and the manufacturing processes are simplified.

Furthermore, in the embodiments where circuit patterns are formed in advance on a transparent plate, and the semiconductor chip is bonded in a flip chip style on the circuit patterns of the transparent plate, which serve as mediums for transferring electrical signals between the semiconductor chip and the circuit board, a semiconductor package for a CCD or other optical semiconductor chip can be made without using a wire bonding process.

Moreover, because a lower surface of the semiconductor chip is directly exposed to the external environment, heat which is generated in the semiconductor chip can be easily dissipated.

Again, the embodiments described above are exemplary only. Numerous variations will be apparent to practitioners in view of the disclosure herein. Our invention is not limited to the examples described herein, but rather is defined by the following claims.

1. A semiconductor package comprising:
an optical semiconductor chip having a first surface with input and output pads thereon;
a dam on the first surface of the semiconductor chip;
a transparent plate bonded to and supported over the first surface of the semiconductor chip by the dam;
a planar insulative substrate having a first surface, an opposite second surface, circuit patterns on the first and second surfaces, and an aperture through the substrate, wherein the circuit patterns on the first and second surfaces are electrically connected and said semiconductor chip is within said aperture;
conductive wires each electrically connected between an input and output pad of the semiconductor chip and a circuit pattern of the first surface of the substrate; and
an encapsulating material within said aperture and covering the wires.

2. The semiconductor package of claim 1, wherein the semiconductor chip has a second surface opposite the first surface thereof, and the second surface of the chip, the second surface of the substrate, and a surface of the encapsulating material are in a same horizontal plane.

3. The semiconductor package of claim 1, wherein the dam is formed from a group consisting of a film adhesive, a double-sided adhesive tape, and a resin layer.

4. The semiconductor package of claim 1, further comprising input and output connectors electrically connected to the circuit patterns of the second surface of the substrate.

5. A semiconductor package comprising:
an optical semiconductor chip having a first surface with input and output pads thereon;
a planar insulative substrate having a first surface, an opposite second surface, circuit patterns on the first and second surfaces, and an aperture through the substrate, wherein the circuit patterns on the first and second surfaces are electrically connected and said semiconductor chip is within said aperture;
a transparent plate positioned over the aperture, the first surface of the semiconductor chip, and the first surface of the substrate, said plate having circuit patterns formed on a first surface thereof; and
pairs of conductive bumps, wherein one bump of each said pair is electrically connected between one of the input and output pads of the semiconductor chip and an inner end of one of the circuit patterns of the plate, and the other bump of said pair is electrically connected between one of the circuit traces of the first surface of the substrate and an opposite outer end of the respective circuit pattern of the plate.

6. The semiconductor package of claim 6, further comprising an encapsulating material in said aperture.

7. The semiconductor package of claim 7, wherein the semiconductor chip has a second surface opposite the first surface thereof, and the second surface of the chip, the second surface of the substrate, and a surface of the encapsulating material are in a same horizontal plane.

8. A semiconductor package comprising:
an optical semiconductor chip having a first surface with input and output pads thereon;
a transparent plate over the first surface of the semiconductor chip, said plate being bonded to the semiconductor chip;
a planar insulative substrate having a first surface with circuit patterns thereon and an aperture through the substrate, wherein the semiconductor chip is within said aperture; and
a plurality of electrically conductive paths, each path extending between an input and output pad of the semiconductor chip and a circuit pattern of the first surface of the substrate.

9. The semiconductor package of claim 8, wherein the electrically conductive paths include a portion on the transparent plate.

10. The semiconductor package of claim 8, wherein the electrically conductive paths include conductive wires, and each wire extends between an input and output pad of the semiconductor chip and a circuit pattern of the first surface of the substrate.

11. The semiconductor package of claim 8, wherein the transparent plate spans the aperture and covers an inner subportion of the first surface of the substrate around said aperture.

12. The semiconductor package of claim 8, wherein the semiconductor chip is in a flip chip style connection with circuit patterns on a juxtaposed surface of the transparent plate.

13. A method for manufacturing a semiconductor package, comprising the steps of:
providing an optical semiconductor chip having a first surface with input and output pads thereon;
placing a transparent plate over the first surface of the semiconductor chip, and attaching said plate to the semiconductor chip;
providing a planar insulative substrate having a first surface with circuit patterns thereon, and an aperture through the substrate;
placing and supporting the semiconductor chip within said aperture; and
electrically connecting the input and output pads of the semiconductor chip to the circuit traces of the first surface of the substrate.

14. The method of claim 13, wherein electrically connecting the input and output pads to the circuit traces comprises bonding a wire between each input and output pad and one of the circuit traces, and further comprising
applying an encapsulating material over said bond wires and within said aperture.

15. The method of claim 14, wherein the insulative substrate includes a second surface opposite the first surface thereof, and the encapsulant material is applied and the semiconductor material is placed so that surfaces of the semiconductor chip and the encapsulant material are in a same plane as the second surface of the substrate.

16. The method of claim 13, wherein the insulative substrate includes a second surface opposite the first surface; and
further comprising attaching a tape to the second surface of the substrate and over the aperture,
wherein placing the semiconductor chip within said aperture includes placing a second surface of the semiconductor chip on said tape.

17. The method of claim 16, further comprising removing said tape.

18. The method of claim 13, wherein the transparent plate is bonded to the semiconductor chip prior to the placing of the semiconductor chip within said aperture.

19. The method of claim 18, further comprising providing a wafer of the semiconductor chips, and singulating the semiconductor chip from the wafer after the transparent plate is bonded to the semiconductor chip.

20. The method of claim 13, further comprising applying a dam on the first surface of the semiconductor chip inside said input and output pads, wherein said dam attaches the transparent plate to the semiconductor chip.

21. The method of claim 13, wherein said transparent plate includes circuit patterns on a surface thereof that is juxtaposed with the first surfaces of the semiconductor chip and the insulative substrate, and
wherein electrically connecting the input and output pads to the circuit patterns of the first surface of the substrate includes electrically connecting the input and output pads to the circuit patterns of the first surface of the substrate through the circuit patterns of the transparent plate.

22. The method of claim 21, wherein the circuit patterns of the transparent plate include opposing inner and outer ends, and further comprising:
electrically connecting the inner end of each conductive pattern of the transparent plate to an input and output pad through a conductive bump therebetween; and
electrically connecting the outer end of each conductive pattern of the transparent plate to a circuit pattern of the first surface of the substrate through a conductive bump therebetween.
